(19) United States
(12) Patent Application Publication
(10) Pub. No.: US 2022/0199363 A1
(43) Pub. Date: Jun. 23, 2022

(54) PLASMA PROCESSING APPARATUS AND PLASMA PROCESSING METHOD

(71) Applicant: Tokyo Electron Limited, Tokyo (JP)

(72) Inventor: Yusuke AOKI, Miyagi (JP)

(73) Assignee: Tokyo Electron Limited, Tokyo (JP)

(21) Appl. No.: 17/560,285

(22) Filed: Dec. 23, 2021

(30) Foreign Application Priority Data
Dec. 23, 2020 (JP) 2020-213117

(51) Int. Cl. H01J 37/32

(52) U.S. Cl. CPC H01J 37/32009; H01J 2237/06375; H01J 2237/334; H01J 37/32532

(57) ABSTRACT

There is provided a plasma processing apparatus comprising: a chamber where a substrate is disposed and processed by plasma generated therein; a substrate attraction portion disposed in the chamber, having therein an electrode, and configured to attract the substrate by a voltage applied to the electrode; a conductive member disposed in the chamber; and a voltage supply configured to apply a voltage to the electrode. A reference potential terminal of the voltage supply is connected to the conductive member, and the voltage supply applies a voltage having as a reference potential a potential of the conductive member to the electrode.

### CROSS-REFERENCE TO RELATED APPLICATIONS

This application claims priority to Japanese Patent Application No. 2020-213117 filed on Dec. 23, 2020, the entire contents of which are incorporated herein by reference.

### TECHNICAL FIELD

Various aspects and embodiments of the present disclosure relate to a plasma processing apparatus and a plasma processing method.

### BACKGROUND

For example, Japanese Laid-open Patent Publication No. 2004-47511 discloses a technique for applying an antistatic voltage to a chuck electrode in the case of removing residual charges of a wafer attracted on an electrostatic chuck using plasma of an inert gas in order to quickly release an object attracted on the electrostatic chuck. The antistatic voltage corresponds to a self-bias potential of the wafer at the time of plasma application.

### SUMMARY

The present disclosure provides a plasma processing apparatus and a plasma processing method capable of suppressing excessive charging of a substrate during plasma processing.

In accordance with an aspect of the present disclosure, there is provided a plasma processing apparatus comprising: a chamber where a substrate is disposed and processed by plasma generated therein; a substrate attraction portion disposed in the chamber, having therein an electrode, and configured to attract the substrate by a voltage applied to the electrode; a conductive member disposed in the chamber; and a voltage supply configured to apply a voltage to the electrode. A reference potential terminal of the voltage supply is connected to the conductive member, and the voltage supply applies a voltage having as a reference potential a potential of the conductive member to the electrode.

### BRIEF DESCRIPTION OF THE DRAWINGS

The objects and features of the present disclosure will become apparent from the following description of embodiments, given in conjunction with the accompanying drawings, in which:

FIG. 1 shows an example of a plasma processing apparatus according to an embodiment of the present disclosure;

FIG. 2 is an enlarged view of a ring assembly;

FIG. 3 is a circuit diagram showing an example of connection relationship between an electrode in an electrostatic chuck, an edge ring, a variable DC power supply, and a switch;

FIG. 4 shows an example of an equivalent circuit in an attraction process;

FIG. 5 shows an example of an equivalent circuit during plasma processing in a comparative example;

FIG. 6 shows an example of an equivalent circuit at the time of plasma processing in the embodiment;

FIG. 7 shows an example of an equivalent circuit at the time of antistatic processing;

FIG. 8 is a flowchart showing an example of plasma processing according to a first embodiment; and

FIG. 9 is a flowchart showing an example of plasma processing in a second embodiment.

### DETAILED DESCRIPTION

Hereinafter, embodiments of a plasma processing apparatus and a plasma processing method of the present disclosure will be described in detail with reference to the accompanying drawings. The following embodiments are not intended to limit the plasma processing apparatus and the plasma processing method of the present disclosure.

Prior to plasma processing, a substrate is attracted. In the attraction process, a DC voltage of a predetermined magnitude is applied to an electrode in a substrate attraction portion to generate a predetermined electrostatic force between the substrate and the substrate attraction portion for attracting the substrate. However, a self-bias is generated on the substrate during the plasma processing. Therefore, during the plasma processing, the intensity of the electrostatic force between the substrate and the substrate attraction portion changes from a predetermined intensity by the amount of self-bias. When the electrostatic force becomes weaker, the substrate is likely to be displaced from the substrate attraction portion. When the electrostatic force becomes stronger, the following risks occur.

When the electrostatic force between the substrate and the substrate attraction portion becomes stronger, the frictional force between the substrate and the substrate attraction portion increases. Accordingly, the amount of particles generated by the friction between the substrate and the substrate attraction portion may increase due to the difference in the coefficient of thermal expansion between the substrate and the substrate attraction portion. Further, when the substrate is charged by the self-bias generated during the plasma processing, the generated particles are likely to be adhered to the substrate. Further, when the electrostatic force between the substrate and the substrate attraction portion becomes strong, the substrate may jump up or crack in the case of separating the processed substrate from the substrate attraction portion using lift pins or the like.

Therefore, the present disclosure provides a technique capable of suppressing excessive charging of a substrate during plasma processing.

### First Embodiment

<Configuration of Plasma Processing Apparatus 100>

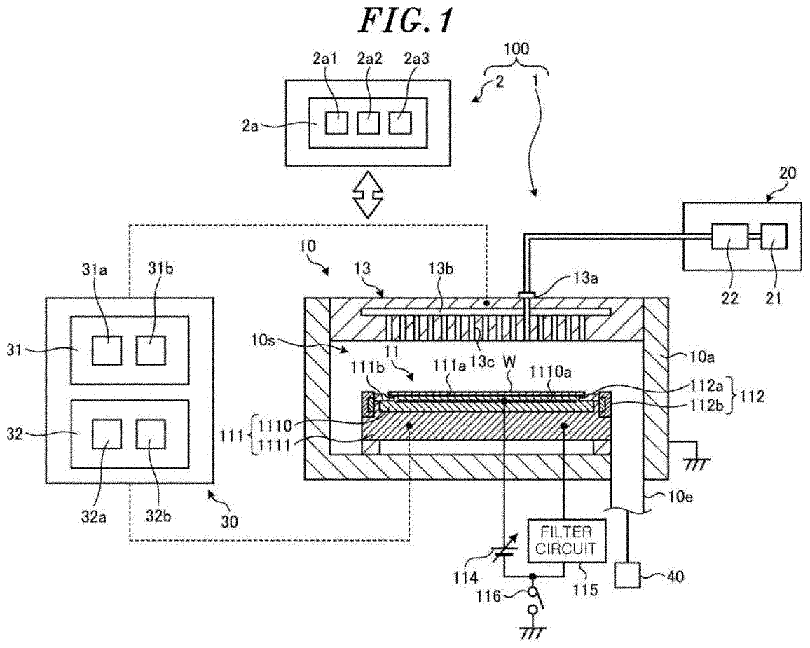

FIG. 1 shows an example of a plasma processing apparatus 100 according to an embodiment of the present disclosure. The plasma processing apparatus 100 includes an apparatus main body 1 and a controller 2. The apparatus main body 1 includes a plasma processing chamber 10, a gas supply 20, a power supply 30, and an exhaust system 40. The apparatus main body 1 further includes a substrate support portion 11 and a gas inlet portion. The gas inlet portion is configured to introduce at least one processing gas into a plasma processing space 10s. The gas inlet portion includes a shower head 13. The substrate support portion 11 is disposed in the plasma processing chamber 10. The shower head 13 is disposed above the substrate support portion 11. In one embodiment, the shower head 13 constitutes at least a part of a ceiling of the plasma processing chamber 10.

The plasma processing chamber 10 has the plasma processing space 10s defined by the shower head 13, a sidewall 10a of the plasma processing chamber 10, and the substrate support portion 11. The plasma processing chamber 10 has at least one gas supply port for supplying at least one processing gas to the plasma processing space 10s, and at least one gas discharge port for discharging gas from the plasma processing space 10s. The sidewall 10a is grounded. The shower head 13 and the substrate support portion 11 are electrically insulated from a housing of the plasma processing chamber 10.

The substrate support portion 11 includes a main body 111 and a ring assembly 112. The ring assembly 112 has an edge ring 112a and a cover ring 112b. The edge ring 112a may be referred to as “focus ring.” The edge ring 112a is an example of a conductive member. The main body 111 has a substrate support surface 111a that is a central region for supporting the substrate W and a ring support surface 111b that is an annular region for supporting the edge ring 112a. The substrate W may be referred to as “wafer.” The ring support surface 111b of the main body 111 surrounds the substrate support surface 111a of the main body 111 in plan view. The substrate W is disposed on the substrate supporting surface 111a of the main body 111, and the edge ring 112a is disposed on the ring supporting surface 111b of the main body 111 to surround the substrate W on the substrate supporting surface 111a of the main body 111.

The main body 111 includes an electrostatic chuck 1110 and a base 1111. The electrostatic chuck 1110 is an example of the substrate attraction portion. The base 1111 includes a conductive member. The conductive member of the base 1111 serves as a lower electrode. The electrostatic chuck 1110 is disposed on the base 1111. An upper surface of the electrostatic chuck 1110 is the substrate support surface 111a. The electrostatic chuck 1110 is provided with an electrode 1110a. One end of a variable DC power supply 114 is connected to the electrode 1110a. The other end of the variable DC power supply 114, i.e., a reference potential terminal of the variable DC power supply 114, is grounded via a switch 116. Further, the other end of the variable DC power supply 114 is connected to the base 1111 via a filter circuit 115. The variable DC power supply 114 is an example of a voltage supply. The electrode 1110a generates an electrostatic force such as a Coulomb force or the like on the substrate support surface 111a by a DC voltage applied from the variable DC power supply 114. Accordingly, the electrostatic chuck 1110 attracts the substrate W disposed on the substrate support surface 111a. The filter circuit 115 suppresses an RF power supplied to the base 1111 from flowing into the variable DC power supply 114.

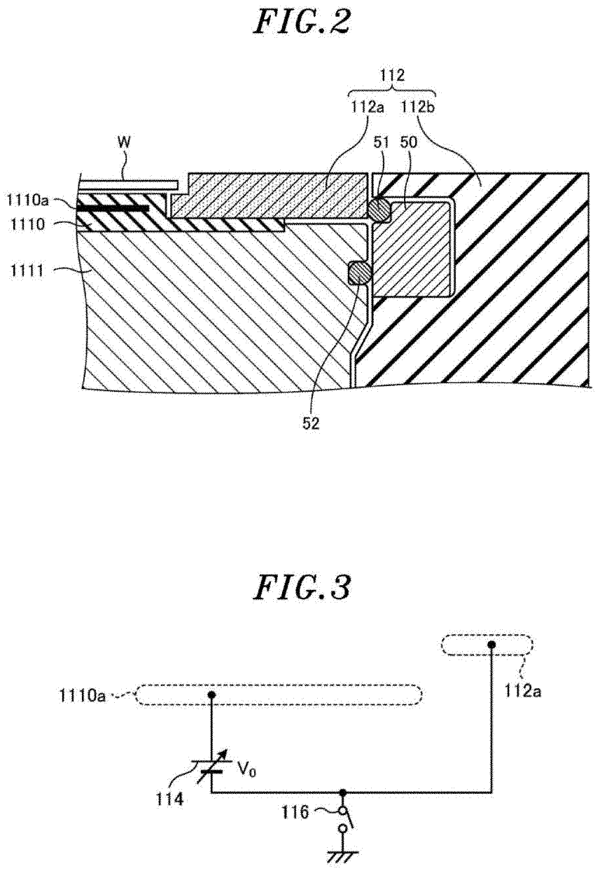

The ring assembly 112 includes one or more annular members. At least one of the annular members is the edge ring 112a and another at least one of the annular members is the cover ring 112b. The edge ring 112a is made of a conductive member containing, e.g., silicon or the like, and the cover ring 112b is made of, e.g., quartz or the like. FIG. 2 is an enlarged view of the ring assembly 112. As shown in FIG. 2, a connecting member 50 made of a conductive member such as metal or the like is disposed in the cover ring 112b, for example.

A spiral-shaped sealing member 51 made of a conductive member such as metal or the like is disposed between the connecting member 50 and the edge ring 112a. The connecting member 50 and the edge ring 112a are electrically connected through the sealing member 51. Further, a spiral-shaped sealing member 52 made of a conductive member such as metal or the like is disposed between the connecting member 50 and the base 1111. The connecting member 50 and the base 1111 are electrically connected through the sealing member 52. Accordingly, the base 1111 and the edge ring 112a are electrically connected through the connecting member 50. Hence, the electrode 1110a in the electrostatic chuck 1110, the edge ring 112a, the variable DC power supply 114, and the switch 116 are connected through the base 1111 as shown in FIG. 3, for example. In FIG. 3, the filter circuit 115 is omitted.

Although not illustrated, the substrate support portion 11 may include a temperature control module configured to adjust at least one of the electrostatic chuck 1110, the ring assembly 112, or the substrate W to a target temperature. The temperature control module may include a heater, a heat transfer medium, a flow path, or a combination thereof. Heat transfer fluid such as brine or gas flows through the flow path. Further, the substrate support portion 11 may include a heat transfer gas supply configured to supply a heat transfer gas to a space between the substrate W and the substrate support surface 111a.

Further, the electrostatic chuck 1110 and the base 1111 are provided with a plurality (e.g., three) lift pins (not shown) penetrating through the electrostatic chuck 1110 and the base 1111. The plurality of lift pins can be moved up and down to penetrate through the electrostatic chuck 1110 and the base 1111. The substrate W that has been subjected to the plasma processing is lifted by the lift pins and unloaded from the plasma processing chamber 10 by a transfer device (not shown) such as a robot arm or the like.

The shower head 13 is configured to introduce at least one processing gas from the gas supply 20 into the plasma processing space 10s. The shower head 13 has at least one gas supply port 13a, at least one gas diffusion space 13b, and a plurality of gas inlet ports 13c. The processing gas supplied to the gas supply port 13a is introduced into the plasma processing space 10s from the plurality of gas inlet ports 13c while passing the gas diffusion space 13b. Further, the shower head 13 includes a conductive member. The conductive member of the shower head 13 serves as an upper electrode. The gas inlet portion may include one or a plurality of side gas injector (SGI) attached to one or a plurality of openings formed in the sidewall 10a, in addition to the shower head 13.

The gas supply 20 may include at least one gas source 21 and at least one flow rate controller 22. In one embodiment, the gas supply 20 is configured to supply at least one processing gas from a corresponding gas source 21 to the shower head 13 through a corresponding flow rate controller 22. The flow rate controllers 22 may include, e.g., mass flow controllers or pressure-controlled flow rate controllers. Further, the gas supply 20 may include one or more flow rate modulation devices for modulating the flow rate of one or more processing gases or causing it to pulsate.

The power supply 30 includes a radio frequency (RF) power supply 31 connected to the plasma processing chamber 10 through at least one impedance matching circuit. The RF power supply 31 is configured to supply at least one RF signal, such as a source RF signal and a bias RF signal, to either one or both of the conductive member of the substrate support 11 and the conductive member of the shower head 13. Therefore, plasma is generated from at least one processing gas supplied to the plasma processing space 10s. Accordingly, the RF power source 31 can function as at least a part of a plasma generator configured to generate plasma from one or more processing gases in the plasma processing chamber 10. Further, by supplying a bias RF signal to the conductive member of the substrate support portion 11, a bias potential is generated at the substrate W, and ions in the generated plasma can be attracted to the substrate W.

In one embodiment, the RF power supply 31 includes a first RF generator 31a and a second RF generator 31b. The first RF generator 31a is connected to either one or both of the conductive member of the substrate support portion 11 and the conductive member of the shower head 13 through at least one impedance matching circuit and is configured to generate a source RF signal for plasma generation. The source RF signal may be referred to as “source RF power.” In one embodiment, the source RF signal has a signal having a frequency within a range of 13 MHz to 150 MHz. In one embodiment, the first RF generator 31a may be configured to generate multiple source RF signals having different frequencies. The generated one or more source RF signals are supplied to either one or both of the conductive member of the substrate support 11 and the conductive member of the shower head 13.

The second RF generator 31b is connected to the conductive member of the substrate support portion 11 through at least one impedance matching circuit, and is configured to generate a bias RF signal. The bias RF signal may be referred to as “bias RF power.” In one embodiment, the bias RF signal has a frequency lower than that of the source RF signal. In one embodiment, the bias RF signal has a frequency within a range of 400 kHz to 13.56 MHz. In one embodiment, the second RF generator 31b may be configured to generate multiple bias RF signals having different frequencies. The generated bias RF signal is supplied to the conductive member of the substrate support 11. In various embodiments, at least one of the source RF signal and the bias RF signal may be pulsated.

Further, the power supply 30 may include a direct current (DC) power supply 32 connected to the plasma processing chamber 10. The DC power supply 32 includes a first DC generator 32a and a second DC generator 32b. In one embodiment, the first DC generator 32a is connected to the conductive member of the substrate support portion 11 and is configured to generate a first DC signal. The generated first DC signal is applied to the conductive member of the substrate support portion 11. In another embodiment, the first DC signal may be applied to another electrode, such as the electrode 1110a in the electrostatic chuck 1110. In one embodiment, the second DC generator 32b is connected to the conductive member of the shower head 13 and is configured to generate a second DC signal. The generated second DC signal is applied to the conductive member of the shower head 13. In various embodiments, at least one of the first DC signal and the second DC signal may be pulsated. The first DC generator 32a and the second DC generator 32b may be provided in addition to the RF power supply 31, and the first DC generator 32a may be provided instead of the second RF generator 31b.

The exhaust system 40 may be connected to a gas outlet 10e disposed at a bottom portion of the plasma processing chamber 10, for example. The exhaust system 40 may include a pressure control valve and a vacuum pump. A pressure in the plasma processing space 10s is adjusted by the pressure control valve. The vacuum pump may include a turbo molecular pump, a dry pump, or a combination thereof.

The controller 2 processes computer-executable instructions that cause the apparatus main body 1 to execute various processes described in the present disclosure. The controller 2 may be configured to control individual elements of the apparatus main body 1 to execute various processes described herein. In one embodiment, a part or all of the controller 2 may be included in the apparatus main body 1. The controller 2 may include, e.g., a computer 2a. The computer 2a may include, e.g., a processor 2a1, a storage 2a2, and a communication interface 2a3. The processor 2a1 may be configured to perform various control operations based on programs stored in the storage 2a2. The processor 2a1 may include a central processing unit (CPU). The storage 2a2 may include a random access memory (RAM), a read only memory (ROM), a hard disk drive (HDD), a solid state drive (SSD), or a combination thereof. The communication interface 2a3 communicates with the apparatus main body 1 through a communication line such as a local area network (LAN) or the like.

<Attraction Process of Substrate W>

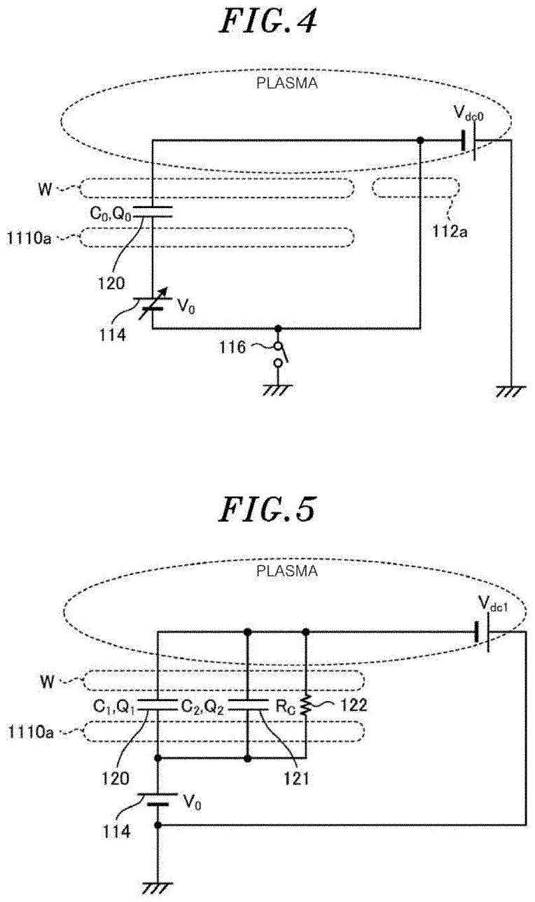

In the case of performing plasma processing on the substrate W, the substrate W is loaded into the plasma processing chamber 10. Then, the substrate W is disposed on the electrostatic chuck 1110, and the attraction process is performed to attract the substrate W on the substrate support surface 111a. In the attraction process, a predetermined DC voltage is applied from the variable DC power supply 114 to the electrode 1110a in the electrostatic chuck 1110. Then, the processing gas is supplied from the gas supply 20 into the plasma processing space 10s through the shower head 13, and the RF source signal is supplied from the RF power supply 31 to either one or both of the conductive member of the substrate support portion 11 and the conductive member of the shower head 13. The gas supplied into the plasma processing space 10s may be an inert gas such as argon gas or the like. Accordingly, plasma is generated in the plasma processing space 10s, and the substrate W and the edge ring 112a are electrically connected through the plasma. Hence, a closed circuit shown in FIG. 4, for example, is formed. During the attraction process, the switch 116 is controlled to be in an open state.

For example, as shown in FIG. 4, a capacitance component 120 having a capacitance C₀ exists between the substrate W and the electrode 1110a. Further, a self-bias V_{dc0} is generated on the substrate W by plasma. Here, in the attraction process, the plasma is generated because the closed circuit is formed through the plasma. However, if the self-bias V_{dc0} generated by the plasma is too large, the substrate W may be damaged in the attraction process before the intended process using the plasma of the processing gas is performed. Therefore, in the attraction process, the self-bias V_{dc0} is small, and weak plasma is generated.

On the assumption that V₀ indicates the DC voltage applied from the variable DC power supply 114 and Q₀ indicates charges accumulated in the capacitance component 120, an electrostatic force F₀ generated between the substrate W and the electrode 1110a is expressed by, e.g., the following Eq. (1), because the self-bias V_{dc0} is so small to be negligible with respect to V₀.

$${F}_{0} = {k ( \frac{{Q}_{0}}{r} )}^{2} = {k ( \frac{{C}_{0} ( {V}_{0} + {V}_{dc 0} )}{r} )}^{2} ≅ {k ( \frac{{C}_{0} {V}_{0}}{r} )}^{2} \qquad ( 1 )$$

In the above Eq. (1), k is a constant, and r is a distance between the substrate W and the electrode 1110a. The DC voltage V₀ applied to the electrode 1110a is preset to a value at which the electrostatic force F₀ has a predetermined intensity.

<Charging of Substrate in Comparative Example>

Here, a configuration in which the reference potential terminal of the variable DC power supply 114 is grounded and the reference potential terminal of the variable DC power supply 114 is not connected to the edge ring 112a will be described as a comparative example. FIG. 5 shows an example of an equivalent circuit during plasma processing in the comparative example.

When the plasma processing on the substrate W is started, a self-biased V_{dc1} larger than the self-biased V_{dc0} in the attraction process is generated. Further, when the plasma processing is started, the attraction state between the substrate W and the substrate support surface 111a changes due to the influence of the plasma, and the capacitance of the capacitance component 120 between the substrate W and the electrode 1110a changes from C₀ to C₁. Further, when the plasma processing is started, a temperature of the substrate W or a surface state of the electrostatic chuck 1110 change due to the influence of the plasma, and the state of the contact surface between the substrate W and the substrate support surface 111a changes. Accordingly, a capacitance component 121 having a capacitance C₂ or a resistance component 122 having a resistance value R_{C} is generated between the substrate W and the electrode 1110a.

Charges Q₁ accumulated in the capacitance component 120 and charges Q₂ accumulated in the capacitance component 121 are expressed as the following Eq. (2). The capacitance C₁ of the capacitance component 120 during the plasma processing is substantially the same as the capacitance C₀ of the capacitance component 120 during the attraction process.

$$\begin{matrix}{Q}_{1} = {C}_{1} ( {V}_{0} + {V}_{dc 1} ) \\ {Q}_{2} = {C}_{2} ( {V}_{0} + {V}_{dc 1} )\end{matrix} \} \qquad ( 2 )$$

Here, the charge Q₀ accumulated in the capacitance component 120 during the attraction process is C₀V₀. Therefore, referring to the above Eq. (2), the charges Q₁ and Q₂ larger than the charges Q₀ accumulated during the attraction process are accumulated in the substrate W during the plasma processing due to the influence of the self-bias V_{dc1}. Accordingly, particles generated in the plasma processing space 10s during the plasma processing are easily attracted to the substrate W.

Further, the electrostatic force F generated between the substrate W and the electrode 1110a by the capacitance component 120 and the capacitance component 121 is expressed as the following Eq. (3), for example.

$$\begin{matrix}F = {F}_{1} + {F}_{2} \\ = {k ( \frac{{Q}_{1}}{r} )}^{2} + {k ( \frac{{Q}_{2}}{r} )}^{2} \\ = {k ( \frac{{C}_{1} ( {V}_{0} + {V}_{dc 1} )}{r} )}^{2} + {k ( \frac{{C}_{2} ( {V}_{0} + {V}_{dc 1} )}{r} )}^{2}\end{matrix} \qquad ( 3 )$$

Here, since the capacitance C₂ of the capacitance component 121 is so small to be negligible with respect to the capacitance C₁ of the capacitance component 120, the electrostatic force F generated between the substrate W and the electrode 1110a can be approximated by the following Eq. (4).

$$F ≅ {k ( \frac{{C}_{1} ( {V}_{0} + {V}_{dc 1} )}{r} )}^{2} \qquad ( 4 )$$

According to the comparison between the above Eq. (4) and Eq. (1), the electrostatic force F during the plasma processing is larger than the electrostatic force F₀ during the attraction process due to the influence of the self-bias V_{dc1}. Therefore, in the comparative example, it is considered that the attractive force between the substrate W and the electrostatic chuck 1110 is excessive during the plasma processing. Since the self-bias V_{dc1} varies depending on the state of plasma processing, it is difficult to accurately set the DC voltage V₀ added with the self-bias V_{dc1}.

When the attractive force between the substrate W and the electrostatic chuck 1110 becomes excessive, the frictional force between the substrate W and the substrate support surface 111a increases. Accordingly, the amount of particles generated by the friction between the substrate W and the substrate support surface 111a may increase due to the difference in the coefficient of thermal expansion between the substrate W and the substrate support surface 111a. Further, when the attractive force between the substrate W and the substrate support surface 111a becomes excessive, the substrate W may jump up or may crack when the substrate W that has been subjected to the plasma processing is separated from the substrate support surface 111a using the lift pins or the like.

<Charging of the Substrate in the Present Embodiment>

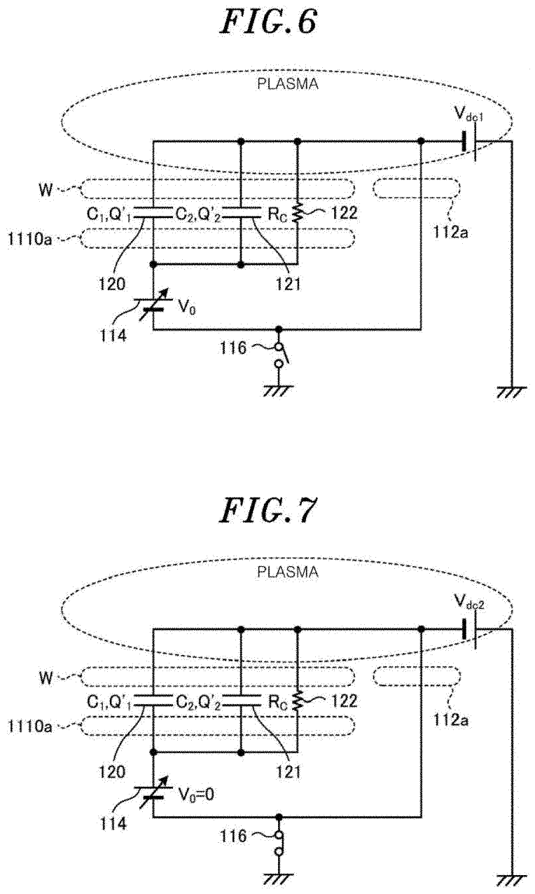

FIG. 6 shows an example of an equivalent circuit during plasma processing in the present embodiment. In the present embodiment, the reference potential terminal of the variable DC power supply 114 is electrically connected to the edge ring 112a, and the reference potential of the variable DC power supply 114 is equal to the potential of the edge ring 112a. By generating plasma in the plasma processing chamber 10, the substrate W and the edge ring 112a are electrically connected through the plasma, and the closed circuit shown in FIG. 6, for example, is formed. During the plasma processing, the switch 116 is controlled to be in an open state.

Also in the present embodiment, when the plasma processing on the substrate W is started, the self-biased V_{dc1} larger than the self-biased V_{dc0} in the attraction process is generated. When the plasma processing is started, the attraction state between the substrate W and the substrate support surface 111a changes due to the influence of the plasma, and the capacitance of the capacitance component 120 between the substrate W and the electrode 1110a changes to C₁. Further, when the plasma processing is started, the temperature of the substrate W or the surface state of the electrostatic chuck 1110 changes due to the influence of the plasma, and the capacitance component 121 having the capacitance C₂ or the resistance component 122 having the resistance value R_{C} is generated between the substrate W and the electrode 1110a.

Here, in the present embodiment, the reference potential terminal of the variable DC power supply 114 is electrically connected to the edge ring 112a, and the substrate W and the edge ring 112a are electrically connected through the plasma. Therefore, the voltage of the self-bias V_{dc1} generated by the plasma is not included in the closed circuit including the variable DC power supply 114. Therefore, the voltages applied to the capacitance component 120 and the capacitance component 121 are maintained at the same voltage V₀ during the attraction process. Accordingly, charges Q1′ accumulated in the capacitance component 120 and charges Q2′ accumulated in the capacitance component 121 are expressed as the following Eq. (5).

$$\begin{matrix}{Q}_{1}^{′} = {C}_{1} {V}_{0} \\ {Q}_{2}^{′} = {C}_{2} {V}_{0}\end{matrix} \} \qquad ( 5 )$$

Further, an electrostatic force F′ generated between the substrate W and the electrode 1110a by the capacitance component 120 and the capacitance component 121 is expressed as, e.g., the following Eq. (6).

$$\begin{matrix}{F}^{′} = {F}_{1}^{′} + {F}_{2}^{′} \\ = {k ( \frac{{Q}_{1}^{′}}{r} )}^{2} + {k ( \frac{{Q}_{2}^{′}}{r} )}^{2} \\ = {k ( \frac{{C}_{1} {V}_{0}}{r} )}^{2} + {k ( \frac{{C}_{2} {V}_{0}}{r} )}^{2}\end{matrix} \qquad ( 6 )$$

Here, the capacitance C₂ of the capacitance component 121 is so small to be negligible with respect to the capacitance C₁ of the capacitance component 120. Further, the capacitance C₁ of the capacitance component 120 is substantially the same as the capacitance C₀ of the capacitance component 120 during the attraction process. Therefore, the electrostatic force F′ generated between the substrate W and the electrode 1110a can be approximated by the following Eq. (7).

$${F}^{′} ≅ {k ( \frac{{C}_{1} {V}_{0}}{r} )}^{2} ≅ {k ( \frac{{C}_{0} {V}_{0}}{r} )}^{2} \qquad ( 7 )$$

Referring to the above Eqs. (1) and (7), in the present embodiment, even during the plasma processing, the electrostatic force F′ equal to the electrostatic force F₀ generated between the substrate W and the electrode 1110a during the attraction process is generated on the substrate W regardless of the magnitude of the self-biased V_{dc1}.

As described above, in the present embodiment, the reference potential terminal of the variable DC power supply 114 is electrically connected to the edge ring 112a, so that the generation of an excessive electrostatic force between the substrate W and the electrode 1110a during the plasma processing is suppressed. Accordingly, an increase in the frictional force between the substrate W and the substrate support surface 111a is suppressed, and the generation of particles by the friction between the substrate W and the substrate support surface 111a that is caused by the difference in the coefficient of thermal expansion between the substrate W and the substrate support surface 111a is suppressed. Further, since the increase in the attractive force between the substrate W and the substrate support surface 111a is suppressed, it is possible to suppress bouncing or cracking of the substrate W that has subjected to the plasma processing in the case of separating the substrate W from the substrate support surface 111a using the lift pins or the like.

When the plasma processing is completed, antistatic treatment is performed. In the antistatic treatment, plasma is generated in the plasma processing chamber 10; the voltage of the variable DC power supply 114 is controlled to 0 (i.e., short-circuit state); and the switch 116 is controlled to a closed state as shown in FIG. 7, for example. Accordingly, the charges accumulated in the substrate W are removed. In the antistatic treatment, the plasma is generated because the closed circuit is formed through the plasma. However, if the self-bias V_{dc2} generated by the plasma is too large, the substrate W that has been subjected to the intended process may be further damaged. Therefore, in the antistatic treatment, the self-biased V_{dc2} is small, and weak plasma is generated.

<Plasma Processing Method>

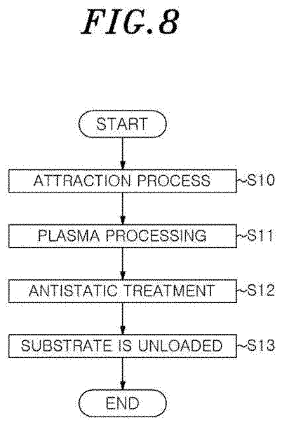

FIG. 8 is a flowchart showing an example of a plasma processing method according to a first embodiment of the present disclosure. For example, the processing illustrated in FIG. 8 is started when an unprocessed substrate W is disposed on the electrostatic chuck 1110. Each of the processes illustrated in FIG. 8 is realized by the controller 2 that controls the individual components of the apparatus main body 1.

First, the attraction process is executed (S10). Step S10 is an example of step a). In step S10, a predetermined voltage V₀ is applied from the variable DC power supply 114 to the electrode 1110a in the electrostatic chuck 1110. Then, the processing gas is supplied from the gas supply 20 into the plasma processing space 10s through the shower head 13, and the RF source signal is supplied from the RF power supply 31 to either one or both of the conductive member of the substrate support portion 11 and the conductive member of the shower head 13. The gas supplied into the plasma processing space 10s may be an inert gas such as argon gas or the like. Accordingly, plasma is generated in the plasma processing space 10s, and the closed circuit shown in FIG. 4, for example, is formed. Then, the substrate W is attracted on the substrate support surface 111a by the electrostatic force F₀ generated by the charge Q₀ accumulated in the capacitance component 120 between the substrate W and the electrode 1110a. Next, the plasma processing is performed on the substrate W after the DC voltage applied to the electrode 1110a is stabilized (S11). Step S11 is an example of step b). In step S11, the processing gas is supplied from the gas supply 20 into the plasma processing space 10s through the shower head 13, and the RF source signal is supplied from the RF power supply 31 to either one or both of the conductive member of the substrate support portion 11 and the conductive member of the shower head 13. Accordingly, plasma is generated in the plasma processing space 10s, and the closed circuit shown in FIG. 6, for example, is formed. Then, by supplying the bias RF signal from the RF power supply 31 to the conductive member of the substrate support portion 11, a bias potential is generated in the substrate W, and ions in the plasma are attracted to the substrate W to perform etching or the like on the substrate W.

Next, after the plasma processing is completed, the antistatic treatment is executed (S12). In step S12, the voltage of the variable DC power supply 114 is controlled to (i.e., short-circuit state), and the switch 116 is controlled to a closed state. Then, the gas supply 20 supplies an inert gas such as argon gas or the like into the plasma processing space 10s through the shower head 13. Then, the RF source signal is supplied from the RF power supply 31 to either one or both of the conductive member of the substrate support portion 11 and the conductive member of the shower head 13. Accordingly, plasma is generated in the plasma processing space 10s, and the charges accumulated in the substrate W are removed.

Next, when the charges accumulated in the substrate W are sufficiently removed, the substrate W is lifted by the lift pins (not shown) and unloaded from the plasma processing chamber 10 by a transfer device (not shown) such as a robot arm or the like (S13). Then, the plasma processing method shown in this flowchart is completed.

As described above, the apparatus main body 1 of the first embodiment includes the plasma processing chamber 10, the electrostatic chuck 1110, the variable DC power supply 114, and the edge ring 112a. In the plasma processing chamber 10, the substrate W is processed by the plasma generated therein. The electrostatic chuck 1110 disposed in the plasma processing chamber 10 has therein the electrode 1110a and attracts the substrate W by the voltage applied to the electrode 1110a. The edge ring 112a is disposed in the plasma processing chamber 10. The variable DC power supply 114 applies a voltage to the electrode 1110a in the electrostatic chuck 1110. The reference potential terminal of the variable DC power supply 114 is connected to the edge ring 112a, and the variable DC power supply 114 applies a voltage having as a reference potential the potential of the edge ring 112a to the electrode 1110a in the electrostatic chuck 1110. Accordingly, excessive charging of the substrate W during the plasma processing can be suppressed.

### Second Embodiment

When the plasma processing is performed, the attraction state between the substrate W and the substrate support surface 111a changes due to the influence of the plasma, and the capacitance of the capacitance component 120 between the substrate W and the electrode 1110a changes from C₀ to C₁. Accordingly, the capacitance component 121 having the capacitance C₂ and the resistance component 122 having the resistance value R_{C} are generated. If the plasma processing time increases, the change in the capacitance C₁ of the capacitance component 120 and the change in the capacitance C₂ of the capacitance component 121 become large compared to those at the start of the plasma processing. Therefore, even if the voltages applied to the capacitance component 120 and the capacitance component 121 are maintained at V₀, the amount of charges accumulated in the capacitance component 120 and the capacitance component 121 changes. Accordingly, the attractive force between the substrate W and the electrostatic chuck 1110 changes.

Therefore, in the present embodiment, the controller 2 controls the variable DC power supply 114 to change the magnitude of the voltage applied to the electrode 1110a of the electrostatic chuck 1110 as the period of the plasma processing elapses. Accordingly, the variation in the attractive force that attracts the substrate W on the electrostatic chuck 1110 is suppressed. For example, the variation in the attractive force that attracts the substrate W on the electrostatic chuck 1110 is measured in advance as the period of the plasma processing elapses. In order to make the attractive force that attracts the substrate W on the electrostatic chuck 1110 constant, the magnitude of the voltage applied to the electrode 1110a is estimated in advance by tests or the like as the period of the plasma processing elapses. During the plasma processing, the controller 2 applies the voltage of the estimated magnitude to the electrode 1110a as the period of the plasma processing elapses. Accordingly, even when the period of the plasma processing is long, the change in the attractive force between the substrate W and the electrostatic chuck 1110 can be reduced.

<Plasma Processing Method>

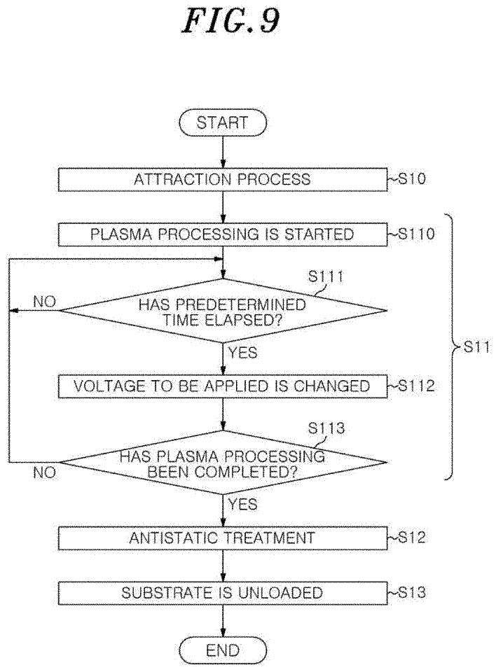

FIG. 9 is a flowchart showing an example of a plasma processing method according to a second embodiment of the present disclosure. The steps in FIG. 9 having the same step reference numerals as those in FIG. 8 indicate the same steps except the following characteristics, and, thus, the description thereof will be omitted.

In step S11 of the present embodiment, first, the plasma processing on the substrate W is started (S110). In step S110, the processing gas is supplied from the gas supply 20 into the plasma processing space 10s through the shower head 13, and the RF source signal is supplied from the RF power supply 31 to either one or both of the conductive member of the substrate support portion 11 and the conductive member of the shower head 13. Accordingly, plasma is generated in the plasma processing space 10s, and the closed circuit shown in FIG. 4, for example, is formed. Then, by supplying the bias RF signal from the RF power supply 31 to the conductive member of the substrate support portion 11, a bias potential is generated in the substrate W, and ions in the plasma are attracted to the substrate W to start processing such as etching or the like on the substrate W.

Next, the controller 2 determines whether or not a predetermined time has elapsed from the start of the plasma processing (S111). If the predetermined time has not elapsed from the start of the plasma processing (S111: No), the processing shown in step S111 is executed again.

On the other hand, when the predetermined time has elapsed from the start of the plasma processing (S111: Yes), the controller 2 changes the magnitude of the voltage applied to the electrode 1110a to the magnitude corresponding to the elapsed time from the start of the plasma processing (S112). Step S112 is an example of step c).

Next, the controller 2 determines whether or not the plasma processing has been completed (S113). When the plasma processing has not been completed (S113: No), the processing shown in step S111 is executed again. On the other hand, when the plasma processing has been completed (S113: Yes), the processing shown in step S12 is executed.

As described above, the plasma processing method according to the second embodiment includes steps a), b), and c). In step a), the substrate W is attracted to the electrostatic chuck 1110 by applying a voltage to the electrode 1110a in the electrostatic chuck 1110 disposed in the plasma processing chamber 10. In step b), the substrate W is processed by the plasma generated in the plasma processing chamber 10. In step c), the variation in the attractive force that attracts the substrate W on the electrostatic chuck 1110 is suppressed by changing the magnitude of the voltage applied to the electrode 1110a in the electrostatic chuck 1110 as the period of the plasma processing elapses. The voltage applied to the electrode 1110a in the electrostatic chuck 1110 has as a reference potential the potential of the edge ring 112a disposed in the plasma processing chamber 10. Accordingly, excessive charging of the substrate W during the plasma processing can be suppressed.

(Other Applications)

The technique of the present disclosure is not limited to the above-described embodiments, and may be variously modified within the scope of the gist thereof.

For example, in the above-described embodiments, the reference potential terminal of the variable DC power supply 114 is connected to the edge ring 112a, and the reference potential of the variable DC power supply 114 is set to be equal to the potential of the edge ring 112a. However, the technique of the present disclosure is not limited thereto. In another embodiment, the cover ring 112b may be formed of a conductive member, and the reference potential terminal of the variable DC power supply 114 may be connected to the cover ring 112b. Alternatively, the edge ring 112a and the cover ring 112b may be formed of a conductive member, and the reference potential terminal of the variable DC power supply 114 may be connected to the edge ring 112a and the cover ring 112b.

In the above-described embodiments, the plasma processing apparatus 100 for performing processing using capacitively coupled plasma (CCP) has been described. However, the plasma source is not limited thereto. The plasma source may be, e.g., inductively coupled plasma (ICP), a microwave excited surface wave plasma (SWP), electron cyclotron resonance (ECR) plasma, helicon wave plasma (HWP), or the like other than the capacitively coupled plasma.

The above-described embodiments are illustrative in all respects and are not restrictive. The above-described embodiments may be implemented in various ways. Further, the above-described embodiments may be omitted, replaced, or changed in various forms without departing from the scope of the appended claims and the gist thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A plasma processing apparatus comprising:
a chamber where a substrate is disposed and processed by plasma generated therein;
a substrate attraction portion disposed in the chamber, having therein an electrode, and configured to attract the substrate by a voltage applied to the electrode;
a conductive member disposed in the chamber; and
a voltage supply configured to apply a voltage to the electrode,
wherein a reference potential terminal of the voltage supply is connected to the conductive member, and
the voltage supply applies a voltage having as a reference potential a potential of the conductive member to the electrode.

2. The plasma processing apparatus of claim 1, wherein the conductive member is an edge ring disposed around the substrate disposed on the substrate attraction portion.

3. The plasma processing apparatus of claim 1, further comprising:
a controller configured to suppress variation in a force that attracts the substrate on the substrate attraction portion by controlling the voltage supply to change a magnitude of the voltage applied to the electrode as a period of processing using the plasma elapses.

4. The plasma processing apparatus of claim 2, further comprising:
a controller configured to suppress variation in a force that attracts the substrate on the substrate attraction portion by controlling the voltage supply to change a magnitude of the voltage applied to the electrode as a period of processing using the plasma elapses.

5. A plasma processing method comprising:
a) attracting a substrate to a substrate attraction portion disposed in the chamber by applying a voltage to an electrode in the substrate attraction portion;
b) processing the substrate using plasma generated in the chamber; and
c) suppressing variation in a force that attracts the substrate on the substrate attraction portion by changing a magnitude of the voltage applied to the electrode as a period of processing using the plasma elapses,
wherein the voltage applied to the electrode has as a reference potential a potential of a conductive member disposed in the chamber.

6. The plasma processing method of claim 5, wherein the conductive member is an edge ring disposed around the substrate disposed on the substrate attraction portion.
